(19) United States
(12) Patent Application Publication
(10) Pub. No.: US 2015/0276870 A1
(43) Pub. Date: Oct. 1, 2015

(54) METHOD AND APPARATUS FOR PERFORMING STATE RETENTION FOR AT LEAST ONE FUNCTIONAL BLOCK WITHIN AN IC DEVICE

(71) Applicants: Michael PRIEL, Netanya (IL); Dan KUZMIN, Givat Shmuel (IL); Sergey SOFER, Rishon Lezion (IL)

(72) Inventors: Michael Priel, Netanya (IL); Dan Kuzmin, Givat Shmuel (IL); Sergey Sofer, Rishon Lezion (IL)

(73) Assignee: Freescale Semiconductor, Inc., Austin, TX (US)

(21) Appl. No.: 14/438,237

(22) PCT Filed: Nov. 7, 2012
(86) PCT No.: PCT/IB2012/056239

§ 371 Date: Apr. 24, 2015

(51) Int. Cl. G01R 31/3177

(52) U.S. Cl. CPC G01R 31/3177

(57) ABSTRACT

A method of performing state retention, for example during power gating, for at least one functional block within an integrated circuit device. The method comprises enabling at least one scan chain within the at least one functional block, scanning out a set of scan chain values from the at least one scan chain, a subset of the set of scan chain values comprising validation values, and writing the set of scan chain values to at least one memory element. The method further comprises retrieving the set of scan chain values from the at least one memory element, and validating the validation values within the retrieved set of scan chain values.

### FIELD OF THE INVENTION

This invention relates to a method and apparatus for performing state retention for at least one functional block within an integrated circuit device.

### BACKGROUND OF THE INVENTION

State Retention Power Gating (SRPG) is one of the most aggressive power management techniques used within integrated circuit devices, allowing the power supply to functional blocks to be gated in order to reduce power leakage whilst enabling gated functional blocks to be subsequently returned to a previous state.

Due to the high power leakage of modern small scale processes, for example 28 nm and below, implementation of SRPG using special flip-flops within a power gated block for state retention during power gating became inefficient and reduced the effectiveness of the power gating. Accordingly, it has become more common place to use scan chains to transfer a block's state to memory, where it may be stored during power gating and from where it may subsequently be retrieved and restored into the block.

A problem with transferring a block's state to memory and the subsequent retrieval and restoration thereof is that there is a need to ensure the integrity of the data that is to be transferred to memory and subsequently retrieved and restored. This is of particular importance in relation to security sensitive blocks, where a change (intentional or not) to state data transferred to memory could disable/weaken security protection. For example, the content of the memory to which a block's state data is transferred could be ‘disturbed’ by hacking, such as toggling memory supply at apparently ‘safe’ levels. Such a safe level refers to a voltage supply level at which there is a high probability that the data stored within the memory is retained correctly, but not 100% guaranteed. The problem is that designers may use special sensors to detect undesired voltage ripple, but if this ripple is within the “safe” region, the sensor may not register it. As such, there is often a “gray zone” when the sensors will not register a security violation event even though the data stored in the memory may potentially be changed. A conventional technique for ensuring the integrity of data being restored from memory following power gating is to use a cyclic redundancy check (CRC) or other similar straightforward data protection technique. However, a problem with such conventional techniques is that the logic/circuitry needed for their implementation involves a large area increase to the IC device, and also significantly increases the low power mode exit/entry time. Furthermore, such data protection techniques are not always able to be implemented with 3^{rd} party vendor modules. For example, if the core or controller implementing the state retention functionality and the memory are provided by different vendors, “stitching” the CRC across the different vendor components is not easy. Also some “low cost” controller solutions for e.g. consumer markets do not provide CRC protection at all.

### SUMMARY OF THE INVENTION

The present invention provides a method of performing state retention for at least one functional block within an integrated circuit device, a state retention module for performing state retention for at least one functional block within an integrated circuit device and a functional block of an integrated circuit device as described in the accompanying claims.

Specific embodiments of the invention are set forth in the dependent claims. These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 illustrates a simplified block diagram of an example of an integrated circuit device comprising a state retention module for performing state retention for at least one functional block within the integrated circuit device.

FIG. 2 illustrates a simplified block diagram of an example of the state retention module of FIG. 1.

FIGS. 3 and 4 illustrate simplified flowcharts of an example of a method of performing state retention for at least one functional block within an integrated circuit device.

### DETAILED DESCRIPTION OF THE PREFERRED EMBODIMENTS

The present invention will now be described with reference to one exemplary embodiment of a method and apparatus for performing state retention for a functional block within an integrated circuit device. However, it will be appreciated that the present invention is not limited to the specific examples herein described with reference to the accompanying drawings. For example, for clarity and ease of understanding, the present invention has been herein described with reference to a state retention module for performing state retention for a functional block within an integrated circuit device. However, it will be appreciated that such a state retention module adapted in accordance with some examples of the present invention may not be limited to performing state retention for only a single functional block within an integrated circuit device, but may equally be arranged to perform state retention for a plurality of functional blocks within one or more integrated circuit devices, independently or as one or more groups of function blocks.

Furthermore, because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

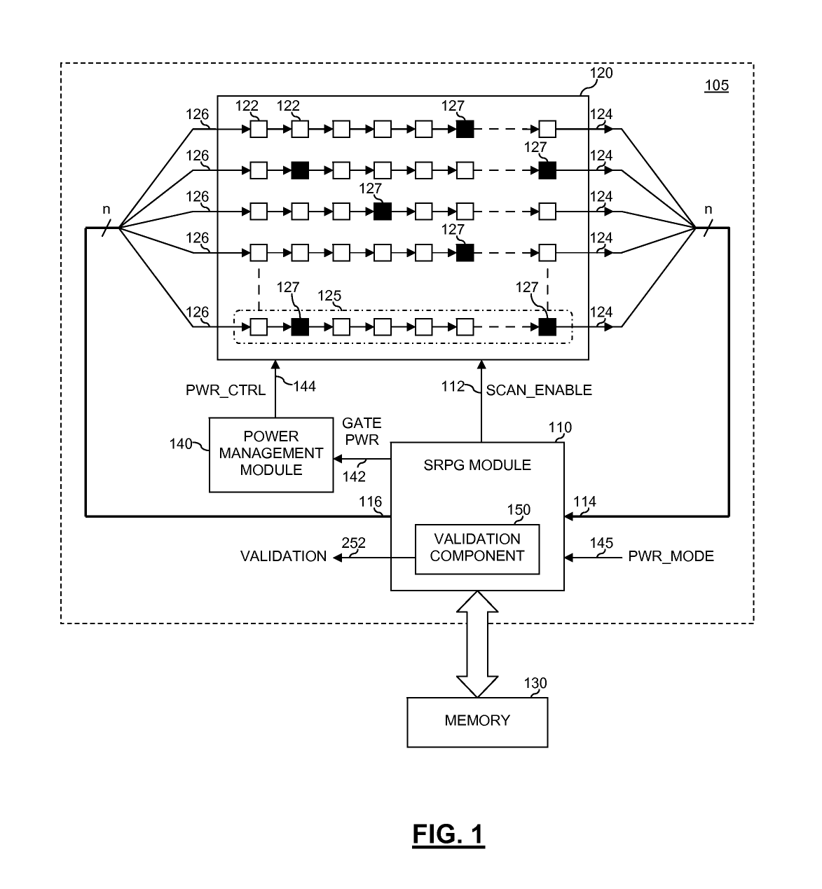

Referring first to FIG. 1, there is illustrated a simplified block diagram of an example of an integrated circuit device 105 comprising a state retention module 110 for performing state retention for at least one functional block within the integrated circuit device 105. In some examples, the state retention module 110 may be implemented within an integrated circuit device comprising at least one die within a single integrated circuit package. A functional block of the integrated circuit device 105 is illustrated generally at 120, and comprises a plurality of data bit storage elements, for example in the form of flip-flops or the like, such as those illustrated at 122. Such a functional block 120 may comprise any type of functional logic and/or circuitry, for example such as a hardware accelerator module, digital signal processing module, central processing core, etc. As is well known in the art, data bit storage elements provide synchronous (clocked) sequential logic within a digital synchronous circuit, with the data bit values stored within the data bit storage elements of a digital synchronous circuit constituting the ‘state’ of the digital synchronous circuit. Thus, the data bit values stored within the data bit storage elements 122 constitute the state of the functional block 120.

The functional block 120 is configurable to operate in a scan mode of operation, whereby the data bit storage elements 122 may be configured into one or more scan chains, such as the scan chain illustrated at 125. As is known in the art, data bit storage elements may be configured into a scan chain by arranging the data bit storage elements into a shift register configuration. In this manner, data bit values stored within the scan chain may be ‘scanned out’ via an output of the scan chain over subsequent clock cycles and/or new data bit values may be ‘scanned in’ via an input of the scan chain over subsequent clock cycles. The implementation of scan chains is well known in the art, and thus need not be described in any greater detail herein.

In the illustrated example, when the state of the functional block 120 is required to be retained (e.g. saved and subsequently restored), the state retention module 110 may be arranged to configure the functional block 120 to operate in the scan mode of operation by enabling the scan chains 125 therein, for example by way of scan enable signal 112. A scan input 114 of the state retention module 110 is operably coupled to outputs 124 of the scan chains 125. In this manner, upon the scan chains 125 being enabled, the state retention module 110 is arranged to receive the data bit values ‘scanned out’ from the functional block 120 (“scan chain values”). The state retention module 110 is further operably coupled to one or more memory elements, such as memory element 130 illustrated in FIG. 1, and is arranged to write the received scan chain values to the memory element(s) 130. Memory element 130 may comprise any appropriate type of memory, such as cache memory, random access memory (RAM), flash memory, etc.

A scan output 116 of the state retention module 110 is operably coupled to inputs 126 of the scan chains 125. In this manner, when the state of the functional block 120 is required to be restored, the state retention module 110 may be arranged to read the scan chain values back from the memory module 130, (re)configure the functional block 120 to operate in the scan mode of operation by enabling the scan chains 125 therein, by way of the scan enable signal 112, and to scan the scan chain values back into the respective scan chains 125.

One example scenario of when it may be desirable to perform state retention for a functional block of in integrated circuit device is as part of a state retention power gating (SRPG) operation, whereby the state of a functional block is required to be retained during power gating of the functional block. Accordingly, in the illustrated example the state retention module 110 comprises an SRPG module arranged to perform state retention power gating for the functional block 120. In particular, the state retention module 110 in the illustrated example is arranged to receive a power mode signal 145 providing an indication of a power mode of the functional block 120 to be implemented. The state retention module 110 is further arranged to output a power gating signal 142 to a power management module 140. The power management module 140 is arranged to configure, via control signal 144, power gating for the functional block 120 in accordance with the power gating signal 142 output by the state retention module 110.

Thus, in response to receiving an indication via the power mode signal 145 that the functional block 120 is to be put into a low power (e.g. gated) mode, the state retention module 110 may be arranged to enable the scan chains 125 within the functional block 120, by way of scan enable signal 112, receive the scan chain values constituting the state of the functional block 120 subsequently scanned out, and to write the scan chain values to memory 130. The state retention module 110 may then set the power gating signal 142 to instruct the power management module 140 to enable power gating of the functional module 120.

In response to subsequently receiving an indication via the power mode signal 145 that the functional block 120 is no longer required to be in the low power mode, the state retention module 110 may be arranged to set the power gating signal 142 to instruct the power management module 140 to disable power gating of the functional module 120, enable the scan chains 125 within the functional block 120, by way of the scan enable signal 112, read the scan chain values back from the memory module 130, (re)configure the functional block 120 to operate in the scan mode of operation by enabling the scan chains 125 therein, by way of the scan enable signal 112, and to scan the scan chain values back into the respective scan chains 125. In this manner, the state of the functional block 120 may be retained from before power gating, and the scan chains disabled to allow normal (functional) operation of the functional module 130 to be resumed from the retained state.

As previously identified, a problem with transferring a functional block's state to memory and the subsequent retrieval and restoration thereof is that there is a need to ensure the integrity of the data that is to be transferred to memory and subsequently retrieved and restored. To this end, in the illustrated example a subset of the set of scan chain values are arranged to comprise validation values, and the state retention module 110 comprises a validation component 150 arranged to validate the validation values upon retrieving the set of scan chain values from memory 130.

For example, a subset of the data bit storage elements of the functional block 120, such as those illustrated at 127, may be arranged to comprise predefined validation values upon the data bit storage elements 122 being configured into scan chains 125. In this manner, the set of scan chain values may be arranged to comprise a subset of validation values that are predefined, and thus known, irrespective of the state of the functional block 120.

By validating a subset of the scan chain values in this manner, an indication of whether the scan chain data stored in the memory element 130 has been ‘changed’ may be determined. For example, it may be assumed that a data corrupting event, such as the content of the memory element 130 being ‘disturbed’ by hacking, such as toggling memory supply at apparently ‘safe’ levels, would cause substantially all, or a significant proportion of, the set of scanned chained data to be affected, albeit not necessarily causing a change in all of the data values. For example, if such an event would cause the data values to be forced to, say, a logical ‘0’ value, then those scan chain values already comprising a logical ‘0’ value would be affected but not result in a change of their value. Thus, validation of only a relatively small subset of the scan chain values may be sufficient to detect such an event, and thus to determine the validity of the retrieved scan chain data values.

In some examples, the data bit storage elements 127 arranged to comprise the predefined validation values upon the data bit storage elements 122 being configured into scan chains 125 may comprise dedicated validation bit storage elements, whereby such data bit storage elements 127 do not have a functional role during a normal operating mode of the functional block 120 (i.e. when the scan chains 125 are not enabled, as opposed to the scan mode of the functional block 120), and are arranged to substantially permanently comprise their respective validation bit values whilst the functional module 120 is powered. In this manner, such dedicated validation bit storage elements 127 may be considered as comprising ‘dummy’ data bit storage elements within the functional module 120.

However, it is contemplated that the present invention is not limited to the use of such ‘dummy’ data bit storage elements to implement the data bit storage elements 127 arranged to comprise the predefined validation values upon the data bit storage elements 122 being configured into scan chains 125. For example, such data bit storage elements 127 may comprise a subset of the ‘functional’ data bit storage elements 122 of the functional module 120 (i.e. data bit storage elements that do have a functional role during the normal operating mode of the functional block 120) which are arranged to be configured to comprise the predefined validation values upon the data bit storage elements 122 being configured into scan chains 125. For example, in the illustrated example the subset of validation data bit storage elements 127 may be arranged to overwrite their current data bit values with predefined validation values upon the scan enable signal 112 being set to enable the scan chains 125.

In some examples, the validation values may be arranged to be located within a scanned sequence of the set of scan chain values such that, upon being written to the memory element 130, the validation values are dispersed within the memory element 130. For example, the validation values may be arranged to be located within the scanned sequence of the set of scan chain values such that, upon being written to the memory element 130, the validation values are evenly distributed within the at least one memory element 130. In this manner, by dispersing the validation values within the memory element 130, the subsequent validation of the validation values upon their retrieval from the memory element 130 provides an indication of the validity of scan chain data values distributed throughout the memory element 130.

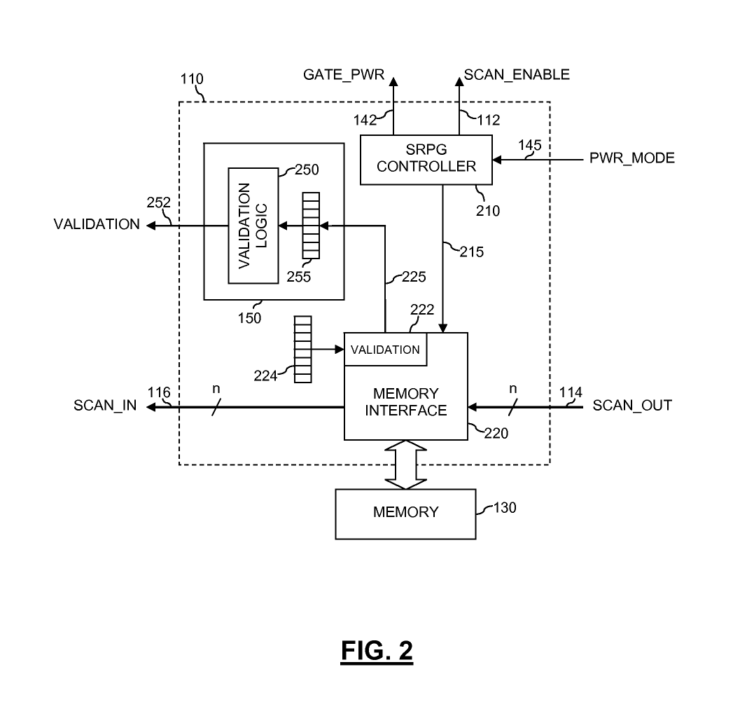

FIG. 2 illustrates a simplified block diagram of an example of the state retention module 110 in greater detail. In the example illustrated in FIG. 2, the state retention module 110 comprises a state retention (power gating) controller 210 arranged to receive the power mode signal 145, and to output the scan enable signal 112 and power gating signal 142. The state retention module 110 further comprises a memory interface 220 operably coupled to the scan input 114 and scan output 116 of the state retention module 110, and as such arranged to receive scan chain values scanned out from the functional module 110 and to output scan chain values to be scanned into the functional module 110. The memory interface 220 is further operably coupled to the memory element 130, and arranged to read and write scan chain data values from and to the memory element 130. Specifically, in the illustrated example the memory interface 220 is arranged to receive a control signal 215 output by the state retention controller 210, and to receive scan chain values scanned out of the functional block 120 and write them to the memory element 130, and to retrieve scan chain values from the memory element 130 and output them to be scanned into the functional block 120, in accordance with the control signal 215 output by the state retention controller 210.

The memory interface 220 is further arranged to make the validation values within the scan chain values retrieved from the memory element 130 available to the validation component 150, as indicated generally at 225. For example, and as illustrated in FIG. 2, the memory interface 220 may comprise a validation data component 222 arranged to identify addresses in the memory element 130 at which the validation values are stored.

For example, the memory element 130 may be arranged to always write the set of scan chain values to the same predetermined address range in memory. Accordingly, the validation values will always be stored at the same addresses in the memory element 130, and the validation component 222 may be preconfigured to identify those addresses in the memory element 130 at which the validation values are stored.

Alternatively, the validation data component 222 may be arranged to identify the addresses in the memory element 130 at which the validation values are stored based on, say, a starting address from which the set of scan chain values are stored. For example, the validation data component 222 may be provided with address offset values corresponding to the relative addresses of the validation values with respect to the starting address at which the set of scan chain values are stored. In the example illustrated in FIG. 2, the address offset values may be provided within a programmable register, such as illustrated at 224. In this manner, the address offset values may be configured in accordance with the location of the validation values within the scanned sequence of the set of scan chain values. In this manner, validation data component 222 may be configured to identify the addresses in memory at which validation values are stored for different functional blocks for which validation values may be located at different locations within their respective scanned sequence of scan chain values.

In some examples, the validation data component 222 may be arranged to identify addresses in the memory element 130 at which the validation values are stored upon the scan chain values being written to memory 130. In this manner, upon the scan chain values subsequently being retrieved from memory, the validation data component 222 is already aware of the addresses at which the validation values are stored, and thus able to quickly extract the relevant values from the retrieved set of scan chain values based on the identified addresses, and provide them to the validation component 150.

For example, the validation component 150 may comprise a register 255 into which the memory element 130 may be arranged to load the validation values retrieved from the memory element 130. The validation component 150 may further comprise a validation logic module 250 arranged to output a validation signal 252 based at least partly on the data values held within the register 255. For example, the validation logic module 250 may comprise logic, such as combinational logic, arranged to receive the data values held within the register 255, and to output a first logical value (e.g. a logical ‘0’ value) if all the validation values within a retrieved set of scan chain values, and thus held within the register 255, match a predefined set of validation values, and to output a second logical value (e.g. a logical ‘1’ value) if at least one validation value within a retrieved set of scan chain values held within the register 255 does not match a corresponding predefined value. In this manner, the validation module 150 may be arranged to output an error signal (comprising the second logical value) if at least one of the validation signals is not ‘validated’; i.e. does not match a corresponding predefined value.

The validation signal 252 may be provided to, say, a central processing unit or other internal or external component (not shown). In this manner, upon an error signal being output by the validation component 150 indicating that one or more validation values have not been validated, the central processing unit (or other component) may initiate appropriate action, for example putting the functional block 120 and/or any other components dependent on the correct functioning of the functional block 120 into a ‘safe’ mode, or simply providing an indication to a user that the restored state of the functional block 120 may not be valid.

Advantageously, the validation of the retrieved validation values in this manner may be performed substantially concurrently with the retrieved set of scan chain values being scanned back into the functional block 120. As a result, the validation of the scan chain values (based on the validation of the subset of validation values) may be performed substantially without any delays to the scanning out from the functional block 120 and storage in memory 130 of the scan chain values, or to the retrieval and scanning back in to the functional block 120 of the scan chain values. Thus, in the illustrated example in which the state retention forms a part of a state retention power gating procedure, the retrieved scan chain values may be validated substantially without any increases to the low power mode exit and entry times. Furthermore, since in the illustrated example only a simple register 255 and combinational logic module 250 is required to perform such validation, the additional area required to implement the validation module 150 is minimal.

This is in contrast to the conventional techniques such as using a cyclic redundancy check (CRC) or other similar straightforward data protection technique, in which the logic/circuitry needed for their implementation involves a large area increase to the IC device, and also significantly increases the low power mode exit/entry time. Furthermore, because of the minimal additional circuit requirements and substantially concurrent implementation, examples of the invention are capable of being implemented with 3^{rd} party vendor modules.

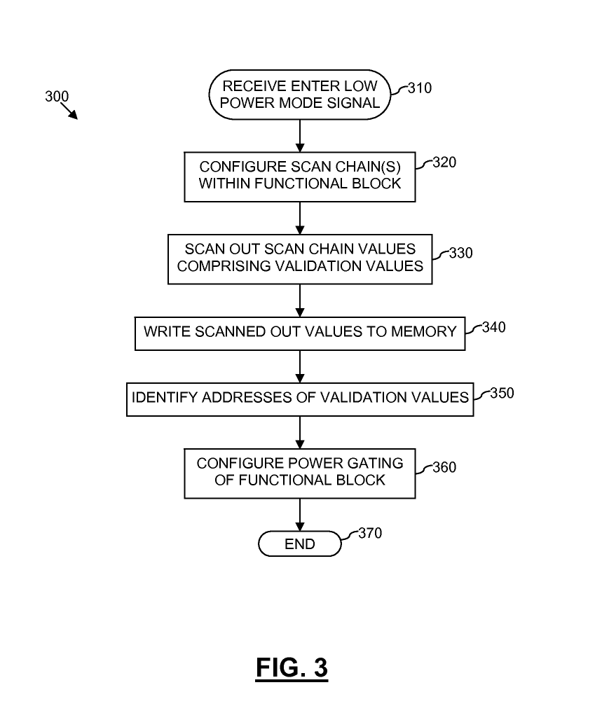

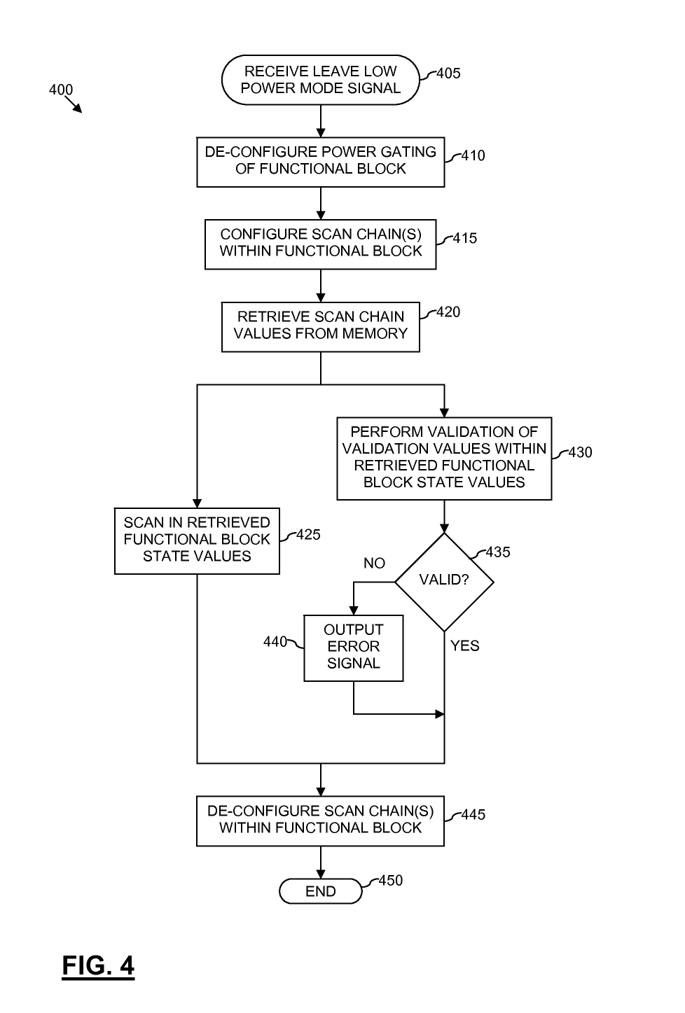

Referring now to FIGS. 3 and 4, there are illustrated simplified flowcharts 300, 400 of an example of a method of performing state retention for at least one functional block within an integrated circuit device, such as may be implemented within the state retention module 110 of FIGS. 1 and 2. In the illustrated example the method of performing state retention forms part of a method of performing state retention power gating. As such, and referring first to the flowchart 300 of FIG. 3, the method starts at 310 with the receipt of a signal indicating that the functional block(s) is/are to be put into a low power mode. Next, at 320, the method comprises configuring one or more scan chains within the functional block(s). A set of scan chain values are then scanned out from the scan chain(s) configured within the functional block(s) at 330; a subset of the set of scan chain values comprising validation values, such as described above with reference to FIGS. 1 and 2. The scan chain values scanned out of the function block(s) are then written to memory, at 340. Next, at 350, addresses (relative or absolute) in memory to which the subset of validation values are written may be identified. In the illustrated example, power gating of the functional block(s) is then configured at 360, and this part of the method ends at 370.

Referring now to the flowchart 400 of FIG. 4, this part of the method starts at 405 with the receipt of a signal indicating that the functional block(s) is/are no longer required to be in the low power mode. Next, at 410, the method comprises de-configuring power gating of the functional block(s), followed by re-configuring (if not already configured) of the scan chain(s) within the functional block(s) at 415. Next, at 410, the scan chain values are then retrieved from memory. The retrieved scan chain values may then be scanned into the scan chain(s) within the functional block(s), at 415, in order to restore the state of the functional block(s). In the illustrated example, substantially concurrently to scanning the retrieved scan chain values back into the functional block(s), validation of the subset of validation values within the retrieved scan chain values is performed, at 430, such as described above with reference to FIGS. 1 and 2. For example, the method may comprise validating retrieved scan chain values in accordance with the identified addresses for validation values. If one or more of the validation values within the retrieved scan chain values are not validated, at 435, an error signal is output, at 440. Having scanned the retrieved scan chain values back into the functional block(s), and having performed the validation of the validation values within the retrieved scan chain values, the method moves on to 445, where the scan chain(s) within the functional block(s) is/are de-configured, and the method ends at 450.

In the foregoing specification, the invention has been described with reference to specific examples of embodiments of the invention. It will, however, be evident that various modifications and changes may be made therein without departing from the broader spirit and scope of the

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. For example, in the illustrated example, the state retention module 110 has been illustrated as a discrete component relative to the power management module 140. However, it is contemplated that in some examples the state retention module 110 may be implemented as an integral part of the power management module 140.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. For example, in some examples, the memory element 130, state retention module 110 and the functional block(s) 120 may be implemented within a single integrated circuit device. Alternatively, the examples may be implemented as any number of separate integrated circuits or separate devices interconnected with each other in a suitable manner. For example, the memory element 130 within which the scan chain values are written and subsequently retrieved may be implemented within a separate integrated circuit device to that of the state retention module 110 and/or the respective functional block(s) 120.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A method of performing state retention for at least one functional block within an integrated circuit device, the method comprising:
enabling at least one scan chain within the at least one functional block;
scanning out a set of scan chain values from the at least one scan chain, a subset of the set of scan chain values comprising validation values; and
writing the set of scan chain values to at least one memory element, the method further comprising:
retrieving the set of scan chain values from the at least one memory element; and
validating the validation values within the retrieved set of scan chain values.

2. The method of claim 1, wherein the method further comprises generating an error signal if at least one validation value is not validated.

3. The method of claim 1, wherein the subset of validation values within the set of scan chain values scanned out of the at least one scan chain comprise predefined values.

4. The method of claim 3, wherein enabling the at least one scan chain within the at least one functional block comprises configuring a set of data bit storage elements within the at least one functional block into at least one shift register configuration; a subset of the set of data bit storage elements being arranged to comprise the predefined validation values upon the at least one scan chain being enabled.

5. The method of claim 1, wherein the method comprises providing the validation values within the retrieved set of scan chain values to a logic module, the logic module being arranged to:
output a first logical value if all of the validation values within the retrieved set of scan chain values match corresponding predefined values; and
output a second logical value if at least one of the validation values within the retrieved set of scan chain values does not match a corresponding predefined value.

6. The method of claim 1, wherein the validation values are arranged to be located within a scanned sequence of the set of scan chain values such that, upon being written to the at least one memory element, the validation values are dispersed within the at least one memory element.

7. The method of claim 6, wherein the validation values are arranged to be located within the scanned sequence of the set of scan chain values such that, upon being written to the at least one memory element, the validation values are evenly distributed within the at least one memory element.

8. The method of claim 1, wherein the method comprises identifying addresses in memory to which the subset of validation values are written, and validating retrieved scan chain values in accordance with the identified address.

9. The method of claim 1, wherein the method further comprises scanning the retrieved set of scan chain values into the at least one scan chain concurrently with validating the validation values within the retrieved set of scan chain values.

10. (canceled)

11. The method claim 1, wherein the method comprises, in response to receiving an indication that the at least one functional block is required to be put into a low power mode:
enabling at least one scan chain within the at least one functional block;
scanning out a set of scan chain values from the at least one scan chain, a subset of the set of scan chain values comprising validation values;
writing the set of scan chain values to at least one memory element; and
enabling power gating of the at least one functional block, the method further comprising, in response to subsequently receiving an indication that the at least one functional block is no longer required to be in the low power mode:
disabling power gating of the at least one functional block;
retrieving the set of scan chain values from the at least one memory element; and
validating the validation values within the retrieved set of scan chain values.

12. A state retention module for performing state retention for at least one functional block within an integrated circuit device, the state retention module being arranged to:
enable at least one scan chain within the at least one functional block;
receive a set of scan chain values from the at least one scan chain, a subset of the set of scan chain values comprising validation values; and
write the set of scan chain values to at least one memory element, the state retention module being further arranged to:
retrieve the set of scan chain values from the at least one memory element; and
validate the validation values within the retrieved set of scan chain values.

13. The state retention module of claim 12, wherein the state retention module is arranged to perform state retention power gating for the at least one functional block.

14. The state retention module of claim 12 implemented within an integrated circuit device comprising at least one die within a single integrated circuit package.

15. A functional block of an integrated circuit device comprising a set of data bit storage elements configurable into at least one scan chain; wherein a subset of the set of data bit storage elements is arranged to comprise predefined validation values upon the set of data bit storage elements being configured into the at least one scan chain.

16. The functional block of claim 15, wherein the subset of data bit storage elements arranged to comprise predefined validation values are arranged to be located within a scanned sequence of the at least one scan chain such that, upon being written to at least one memory element, the validation values are dispersed within the at least one memory element.

17. The functional block of claim 16, wherein the subset of data bit storage elements arranged to comprise predefined validation values are arranged to be located within a scanned sequence of the at least one scan chain such that, upon being written to at least one memory element, the validation values are evenly distributed within the at least one memory element.
